(19) United States
(12) Patent Application Publication
(10) Pub. No.: US 2021/0343907 A1
(43) Pub. Date: Nov. 4, 2021

(54) FLEXIBLE MICRO LIGHT EMITTING DIODE DISPLAY PANEL, AND MICRO LIGHT EMITTING DIODE DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventors: Yong Fan, Shenzhen (CN); Chiayu Lee, Shenzhen (CN); Yu Shi, Shenzhen (CN)

(21) Appl. No.: 16/624,921

(22) PCT Filed: Nov. 8, 2019
(86) PCT No.: PCT/CN2019/116737

§ 371 Date: Dec. 20, 2019

(30) Foreign Application Priority Data
Aug. 20, 2019 (CN) 201910769899.6

(51) Int. Cl. H01L 33/48; H01L 33/62; G09F 9/30; H01L 25/075

(52) U.S. Cl. CPC H01L 33/483; H01L 25/0753; G09F 9/301; H01L 33/62

(57) ABSTRACT

A flexible micro light emitting diode display panel and a micro light emitting diode display device are provided. The flexible micro light emitting diode display panel includes: a supporting board comprising a top surface, a bottom surface, at least one side surface, and at least one top circular chamfer. The at least one side surface is connected to the top surface and the bottom surface, and the at least one circular chamfer is connected to the top surface and the side surface. A flexible micro light emitting diode substrate includes a display region and at least one frame portion, the display region is formed on the top surface, and the display region comprises micro light emitting diodes. The at least one frame portion is in contact with the at least one top circular chamfer and the side surface, and a printed circuit board electrically connected to the frame portion.

### BACKGROUND OF INVENTION

### Field of Invention

The present application relates to a display technological field, and particular to a flexible micro light emitting diode display panel and a micro light emitting diode display device.

### Description of Prior Art

Compared with organic light emitting diode (OLED) displays, micro light emitting diode (micro LED) displays have the advantages of high luminous efficiency, high color gamut, high brightness, high transparency, low power consumption, good reliability, and long lifespan. They may become the next-generation display panels. In the manufacturing process of micro light emitting diode displays, micro light emitting diode particles need to be transferred and bonded to the TFT substrate. However, the technology of transferring and bonding micro light emitting diode particles is limited by restrictions in developing devices. For example, a problem of alignment of a large number of micro light emitting diode particles transferred to the TFT substrate. At present, it is difficult to manufacture a large-sized micro light emitting diode display panel right away.

Therefore, the technology of using and splicing a plurality of small-sized micro light emitting diode panels to achieve a large-sized micro light emitting diode display seems to be feasible and can be an implication for the development of display panels. Therefore, how to achieve seamless splicing is a key to achieving a large size micro LED display device.

Therefore, it is necessary to provide a flexible micro light emitting diode display panel and a micro light emitting diode display device to solve the problems existing in the prior art.

### SUMMARY OF INVENTION

The present application provides a flexible micro light emitting diode display panel, and a micro light emitting diode display device to achieve a seamless splicing panel with a plurality of micro light emitting diodes to achieve a large-sized micro light emitting diode display device.

For the above purposes, the present application provides a micro light emitting diode display device, the micro light emitting diode display device includes:

at least two flexible micro light emitting diode display panels, where each of the flexible micro light emitting diode display panel comprise:

a supporting board comprising a top surface, a bottom surface, at least one side surface, and at least one top circular chamfer, wherein the at least one side surface is connected to the top surface and the bottom surface, and the at least one top circular chamfer is connected to the top surface and the side surface;

a flexible micro light emitting diode substrate comprising a display region and at least one frame portion, wherein the display region is formed on the top surface, the display region comprises a plurality of micro light emitting diodes, the at least one frame portion is folded and extends to the bottom surface, and the at least one frame portion is in contact with the at least one top circular chamfer and the side surface; and

a printed circuit board electrically connected to the frame portion.

In one embodiment of the present application, the plurality of micro light emitting diodes form a plurality of pixel units, a distance between two adjacent pixel units is defined as a pixel unit distance, and a curvature radius of the top circular chamfer of the supporting board is less than half the pixel unit distance.

In one embodiment of the present application, the frame portion comprises at least one corner cut.

In one embodiment of the present application, the printed circuit board is formed on the bottom surface of the supporting board.

In one embodiment of the present application, the supporting board further comprises at least one bottom circular chamfer, the at least one bottom circular chamfer is connected to the bottom surface and the side surface, and the frame portion is in contact with the bottom circular chamfer.

In one embodiment of the present application, a black tape is disposed between at least two adjacent flexible micro light emitting diode display panels.

In one embodiment of the present application, the black tape is disposed between frame portions of the at least two adjacent flexible micro light emitting diode display panels.

The present application also provides a flexible micro light emitting diode display panel, the flexible micro light emitting diode display panel includes:

a supporting board comprising a top surface, a bottom surface, at least one side surface, and at least one top circular chamfer, wherein the at least one side surface is connected to the top surface and the bottom surface, and the at least one top circular chamfer is connected to the top surface and the side surface;

a flexible micro light emitting diode substrate comprising a display region and at least one frame portion, wherein the display region is formed on the top surface, the display region comprises a plurality of micro light emitting diodes, the at least one frame portion is in contact with the at least one top circular chamfer and the side surface; and

a printed circuit board electrically connected to the frame portion.

In one embodiment of the present application, the plurality of micro light emitting diodes form a plurality of pixel units, a distance between two adjacent pixel units is defined as a pixel unit distance, and a curvature radius of the top circular chamfer of the supporting board is less than half the pixel unit distance.

In one embodiment of the present application, the frame portion comprises at least one corner cut.

In one embodiment of the present application, the printed circuit board is formed on the bottom surface of the supporting board.

In one embodiment of the present application, the supporting board further comprises at least one bottom circular chamfer, the at least one bottom circular chamfer is connected to the bottom surface and the side surface.

The present application also provides a micro light emitting diode display device, the micro light emitting diode display device includes:

at least two flexible micro light emitting diode display panels, where each of the flexible micro light emitting diode display panel comprise:

a supporting board comprising a top surface, a bottom surface, at least one side surface, and at least one top circular chamfer, wherein the at least one side surface is connected to the top surface and the bottom surface, and the at least one top circular chamfer is connected to the top surface and the side surface;

a flexible micro light emitting diode substrate comprising a display region and at least one frame portion, wherein the display region is formed on the top surface, the display region comprises a plurality of micro light emitting diodes, the at least one frame portion is formed on the least one of the top circular chamfer and the side surface; and

a printed circuit board electrically connected to the frame portion.

In one embodiment of the present application, the plurality of micro light emitting diodes form a plurality of pixel units, a distance between two adjacent pixel units is defined as a pixel unit distance, and a curvature radius of the top circular chamfer of the supporting board is less than half the pixel unit distance.

In one embodiment of the present application, the frame portion comprises at least one corner cut.

In one embodiment of the present application, the printed circuit board is formed on the bottom surface of the supporting board.

In one embodiment of the present application, a black tape is disposed between at least two adjacent flexible micro light emitting diode display panels.

The benefit of the present application is that: a gap without display function is reduced by the circular chamfer of the supporting board and the corner cut of the frame portion coupled with flexible micro light emitting diode substrate, a seamless splicing panel with a plurality of micro light emitting diode panels is achieved, thereby achieving a large size micro light emitting diode display device.

### BRIEF DESCRIPTION OF DRAWINGS

In order to make the above content of the present invention more comprehensible, a preferred embodiment is exemplified below, and in conjunction with the accompanying drawings, the detailed description is as follows:

FIG. 1 is a structural side view schematic diagram of a micro light emitting diode display device of one embodiment according to the present application.

FIG. 2 is a top view schematic diagram of a flexible micro light emitting diode display panel of one embodiment in an expansion state according to the present application.

FIG. 3 is a side view schematic diagram of a top circular chamfer of the embodiment of FIG. 1.

FIG. 4 is a top view schematic diagram of a flexible micro light emitting diode display panel of one embodiment in a folded state according to the present application.

### DETAILED DESCRIPTION OF PREFERRED EMBODIMENTS

The following description of the various embodiments is provided to illustrate the specific embodiments of the invention. Directional terms mentioned in the present invention, such as “upper”, “lower”, “previous”, “post”, “left”, “right”, “inside”, “outside”, “side”, etc., are merely references to the direction of the appended drawings. Therefore, the directional terminology used is for the purpose of illustration and understanding of the invention. In the figures, structurally similar elements are denoted by the same reference numerals.

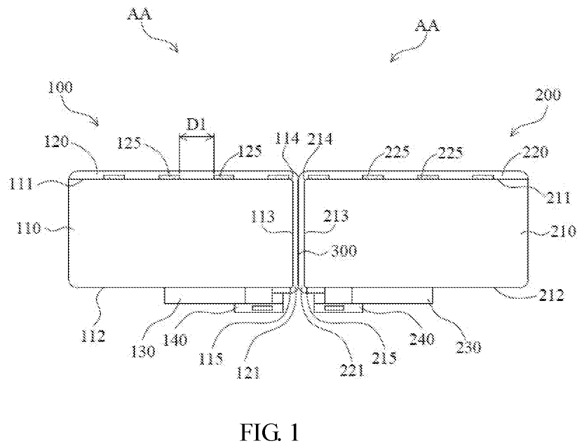

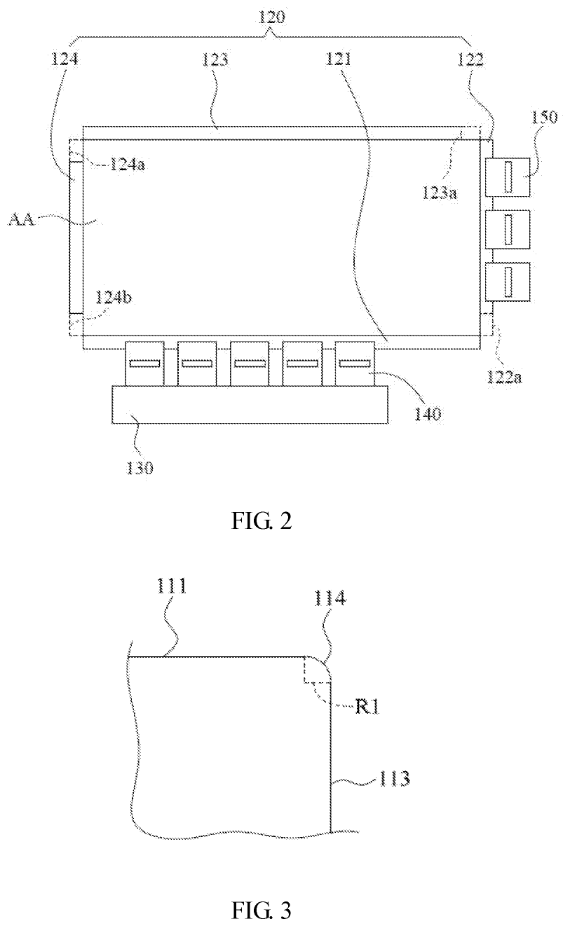

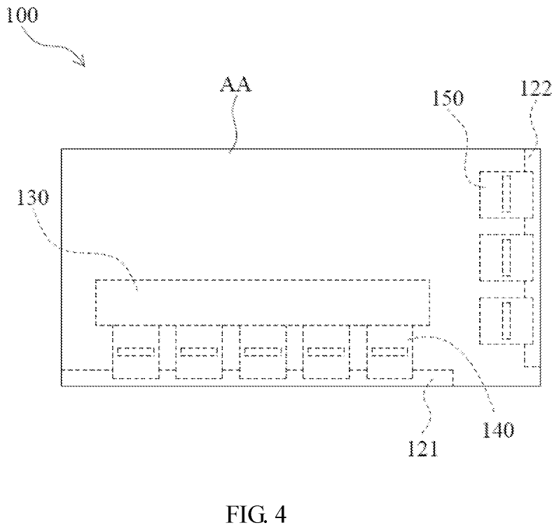

Referring to FIGS. 1-4, FIG. 1 is a structural side view schematic diagram of a micro light emitting diode display device of one embodiment according to the present application. FIG. 2 is a top view schematic diagram of a flexible micro light emitting diode display panel of one embodiment in an expansion state according to the present application. FIG. 3 is a side view schematic diagram of a top circular chamfer of the embodiment of FIG. 1. FIG. 4 is a top view schematic diagram of a flexible micro light emitting diode display panel of one embodiment in a folded state according to the present application.

Referring to FIG. 1, one embodiment of the present application provides a micro light emitting diode display device, the micro light emitting diode display device includes a first flexible micro light emitting diode display panel 100, a second flexible micro light emitting diode display panel 200, and a black tape 300. The micro light emitting diode display device can be a splicing type micro light emitting diode display device.

The first flexible micro light emitting diode display panel 100 includes a supporting board 110, a flexible micro light emitting diode substrate 120, and a printed circuit board (PCB) 130.

The supporting board 110 includes a top surface 111, a bottom surface 112, a side surface 113, and a top circular chamfer 114. The side surface 113 is connected to the top surface 111 and the bottom surface 112, and the top circular chamfer 114 is connected to the top surface 111 and the side surface 113. In addition, the supporting board 110 can also include a bottom circular chamfer 115, and the bottom circular chamfer 115 is connected to the bottom surface 112 and the side surface 113.

Referring FIGS. 1 and 2, the flexible micro light emitting diode substrate 120 includes a display region AA and four frame portions 121, 122, 123, 124. The display region AA is formed on the top surface 111, and the display region AA includes a plurality of micro light emitting diodes formed therein. The frame portion 121 is formed on the top circular chamfer 114 and the side surface 113. Such as FIG. 1, the frame portion 121 can be in contact with the top circular chamfer 114, the side surface 113, the bottom circular chamfer 115 and a part of the bottom surface 112. So, the frame portions 121, 122, 123, 124 can be folded and extend to the bottom surface 112. The frame portions 122, 123, 124 can includes corner cuts 122a, 123a, 124a, 124b of themselves to avoid the frame portions 121, 122, 123, 124 overlapped in folded. It should be understood, the corner cuts can be changed in accordance with the requirements. In addition, the flexible micro light emitting diode substrate 120 can be a multi layers film structure and can include flexible organic film layer. For example, polyimide (PI) can be used for manufacturing a micro light emitting diode substrate 120.

Referring to FIGS. 1 and 3, the plurality of micro light emitting diodes are divided into a plurality of pixel units 125, and a pixel unit distance D1 is defined between two adjacent pixel units 125, a curvature radius R1 of the top circular chamfer 114 is less than half the pixel unit distance D1. It should be understood, a curvature radius of the bottom circular chamfer 115 can be less than half the pixel unit distance. For example, a single the pixel unit 125 can consist of a red micro light emitting diode, a green micro light emitting diode, and a blue micro light emitting diode. It should be understood, the number, the color, and the arrangement of the plurality of the micro light emitting diodes of the pixel unit 125 can be changed by design.

The PCB 130 is electrically connected to the frame portion 121, such as by a chip on film (COF) 140. That is, the COF 140 is connected to the PCB 130 and the frame portion 121. In addition, the frame portion 122 can be connected to a COF 150, the COF 140 can be used for transmitting signals of source and drain electrodes, the COF 150 can be used for transmitting signals of gate electrodes. It should be understood, a connecting relationship and a function between the COF 140 and the COF 150 can be changed by requirements. In addition, the PCB 130 can be electrically connected to the frame portion 121 by other possible technologies.

The second flexible micro light emitting diode display panel 200 includes a supporting board 210, a flexible micro light emitting diode substrate 220 and a PCB 230.

The supporting board 210 includes a top surface 211, a bottom surface 212, a side surface 213, and a top circular chamfer 214. The side surface 213 is connected to the top surface 211 and the bottom surface 212, and the top circular chamfer 214 is connected to the top surface 211 and the side surface 213. In addition, the supporting board 210 can also include a bottom circular chamfer 215, and the bottom circular chamfer 215 is connected to the bottom surface 212 and the side surface 213.

The flexible micro light emitting diode substrate 220 includes a display region AA and a plurality of frame portions, such as the frame portion 221. The display region AA is formed on the top surface 211, and the display region AA includes a plurality of micro light emitting diodes formed therein. The frame portion 223 is formed on the top circular chamfer 214 and the side surface 213. Referring to FIG. 2, the frame portion 221 can be in contact with the top circular chamfer 214, the side surface 213, the bottom circular chamfer 215, and a part of the bottom surface 212. So, the frame portion 221 can be folded and extend to the bottom surface 212. The frame portions 222 can includes corner cuts of themselves to avoid the plurality of frame portions 221 overlapping in folding. It should be understood, the corner cuts can be changed by requirements.

The plurality of micro light emitting diodes are divided into a plurality of pixel units 225, and a pixel unit distance is defined between two adjacent pixel units 225, a curvature radius of the top circular chamfer 214 is less than half the pixel unit distance D1, such as FIG. 3. It should be understood, a curvature radius of the bottom circular chamfer 215 can be less than half the pixel unit distance. For example, a single the pixel unit 225 can consist of a red micro light emitting diode, a green micro light emitting diode, and a blue micro light emitting diode. It should be understood, the number, the color, and the arrangement of the plurality of the micro light emitting diodes of the pixel unit 225 can be changed by design.

The PCB 230 is electrically connected to the frame portion 221, such as by a chip on film (COF) 240. That is, the COF 240 is connected to the PCB 230 and the frame portion 221. In addition, the PCB 130 can be electrically connected to the frame portion 121 by other possible technologies.

Referring to FIG. 4, FIG. 4 illustrates the first flexible micro light diode display panel 100 as an example, in a folding state, the frame portions 121, 122 can be folded to the bottom surface 112 of the supporting board 110, that is, under the display region. So, the frame portions of the flexible micro light emitting diode substrate 120 can be reduced as much as possible, that is, the frame portions of the flexible micro light emitting diode substrate 220 of the second flexible micro light emitting diode display panel 200 can be reduced as much as possible. In this way, the first flexible micro light emitting diode display panel 100 and the second flexible micro light emitting diode display panel 200 can be achieved to be seamless spliced.

In addition, referring to FIG. 1, a black tape 300 is disposed between the first flexible micro light emitting diode display panel 100 and the second flexible micro light emitting diode display panel 200. The black tape 300 is disposed between the frame portion 121 and the frame portion 221 to splice and connect to the first flexible micro light emitting diode display panel 100 and the second flexible micro light emitting diode display panel 200.

The benefit of the present application is that: a gap without display function is reduced by the circular chamfer of the supporting board and the corner cut of the frame portion coupled with flexible micro light emitting diode substrate, a seamless splicing panel with a plurality of micro light emitting diode panels is achieved, thereby achieving a large size micro light emitting diode display device.

In summary, although the present invention has been disclosed as above with preferred embodiments, the above preferred embodiments are not intended to limit the present invention. Those skilled in the art can make various modifications without departing from the spirit and scope of the present invention. This kind of modification and retouching, therefore, the protection scope of the present invention is subject to the scope defined by the claims.

What is claimed is:

1. A micro light emitting diode display device, comprising:
at least two flexible micro light emitting diode display panels, wherein each of the flexible micro light emitting diode display panel comprise:
a supporting board comprising a top surface, a bottom surface, at least one side surface, and at least one top circular chamfer, wherein the at least one side surface is connected to the top surface and the bottom surface, and the at least one top circular chamfer is connected to the top surface and the side surface;
a flexible micro light emitting diode substrate comprising a display region and at least one frame portion, wherein the display region is formed on the top surface, the display region comprises a plurality of micro light emitting diodes, the at least one frame portion is folded and extends to the bottom surface, and the at least one frame portion is in contact with the at least one top circular chamfer and the side surface; and
a printed circuit board electrically connected to the frame portion.

2. The micro light emitting diode display device of claim 1, wherein the plurality of micro light emitting diodes form a plurality of pixel units, a distance between two adjacent pixel units is defined as a pixel unit distance, and a curvature radius of the top circular chamfer of the supporting board is less than half the pixel unit distance.

3. The micro light emitting diode display device of claim 1, wherein the frame portion comprises at least one corner cut.

4. The micro light emitting diode display device of claim 1, wherein the printed circuit board is formed on the bottom surface of the supporting board.

5. The micro light emitting diode display device of claim 1, wherein the supporting board further comprises at least one bottom circular chamfer, the at least one bottom circular chamfer is connected to the bottom surface and the side surface, and the frame portion is in contact with the bottom circular chamfer.

6. The micro light emitting diode display device of claim 1, wherein a black tape is disposed between at least two adjacent flexible micro light emitting diode display panels.

7. The micro light emitting diode display device of claim 6, wherein the black tape is disposed between frame portions of the at least two adjacent flexible micro light emitting diode display panels.

8. A flexible micro light emitting diode display panel, comprising:
a supporting board comprising a top surface, a bottom surface, at least one side surface, and at least one top circular chamfer, wherein the at least one side surface is connected to the top surface and the bottom surface, and the at least one top circular chamfer is connected to the top surface and the side surface;
a flexible micro light emitting diode substrate comprising a display region and at least one frame portion, wherein the display region is formed on the top surface, the display region comprises a plurality of micro light emitting diodes, the at least one frame portion is in contact with the at least one top circular chamfer and the side surface; and
a printed circuit board electrically connected to the frame portion.

9. The flexible micro light emitting diode display panel of claim 8, wherein the plurality of micro light emitting diodes form a plurality of pixel units, a distance between two adjacent pixel units is defined as a pixel unit distance, and a curvature radius of the top circular chamfer of the supporting board is less than half the pixel unit distance.

10. The flexible micro light emitting diode display panel of claim 8, wherein the frame portion comprises at least one corner cut.

11. The flexible micro light emitting diode display panel of claim 8, wherein the printed circuit board is formed on the bottom surface of the supporting board.

12. The flexible micro light emitting diode display panel of claim 8, wherein the supporting board further comprises at least one bottom circular chamfer, the at least one bottom circular chamfer is connected to the bottom surface and the side surface.

13. A micro light emitting diode display device, comprising:
at least two flexible micro light emitting diode display panels, wherein each of the flexible micro light emitting diode display panel comprise:
a supporting board comprising a top surface, a bottom surface, at least one side surface, and at least one top circular chamfer, wherein the at least one side surface is connected to the top surface and the bottom surface, and the at least one top circular chamfer is connected to the top surface and the side surface;
a flexible micro light emitting diode substrate comprising a display region and at least one frame portion, wherein the display region is formed on the top surface, the display region comprises a plurality of micro light emitting diodes, the at least one frame portion is formed on the least one of the top circular chamfer and the side surface; and
a printed circuit board electrically connected to the frame portion.

14. The micro light emitting diode display device of claim 13, wherein the plurality of micro light emitting diodes form a plurality of pixel units, a distance between two adjacent pixel units is defined as a pixel unit distance, and a curvature radius of the top circular chamfer of the supporting board is less than half the pixel unit distance.

15. The micro light emitting diode display device of claim 14, wherein the frame portion comprises at least one corner cut.

16. The micro light emitting diode display device of claim 13, wherein the printed circuit board is formed on the bottom surface of the supporting board.

17. The micro light emitting diode display device of claim 13, wherein a black tape is disposed between at least two adjacent flexible micro light emitting diode display panels.
